(19) United States
(12) Patent Application Publication
(10) Pub. No.: US 2008/0119060 A1
(43) Pub. Date: May 22, 2008

(54) Inspection systems and methods

(76) Inventor: Francis Goodwin, Halfmoon, NY (US)

Correspondence Address: SLATER & MATSIL LLP, 17950 PRESTON ROAD, SUITE 1000, DALLAS, TX, 75252, US

(21) Appl. No.: 11/601,502

(22) Filed: Nov. 17, 2006

(51) Int. Cl. G02B 21/06; G02B 21/16; G02B 3/08; H01L 21/02

(52) U.S. Cl. 438/795; 359/391; 359/392; 378/43; 359/720; 257/E21.002

(57) ABSTRACT

Inspection systems and methods are disclosed. A preferred embodiment comprises an inspection system including a support for a reticle and a microscope including a lens system. The lens system includes at least one lens comprising at least one Fresnel element, wherein the at least one Fresnel element is non-circular.

### TECHNICAL FIELD

The present invention relates generally to the fabrication of semiconductor devices, and more particularly to inspection systems and methods for reticles used to pattern material layers of semiconductor devices.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece, wafer, or substrate, and patterning the various material layers using lithography. The material layers typically comprise thin films of conductive, semiconductive, and insulating materials that are patterned and etched to form integrated circuits (ICs). There may be a plurality of transistors, memory devices, switches, conductive lines, diodes, capacitors, logic circuits, and other electronic components formed on a single die or chip, for example.

Optical photolithography involves projecting or transmitting light through a pattern comprised of optically opaque or translucent areas and optically clear or transparent areas on a mask or reticle. For many years in the semiconductor industry, optical lithography techniques such as contact printing, proximity printing, and projection printing have been used to pattern material layers of integrated circuits. Lens projection systems and transmission lithography masks are used for patterning, wherein light is passed through the lithography mask to impinge upon a photosensitive material layer disposed on semiconductor wafer or workpiece. After development, the photosensitive material layer is then used as a mask to pattern an underlying material layer. In some lithography systems, such as extreme ultraviolet (EUV) lithography systems, reflective lenses and masks are used to pattern a photosensitive material layer disposed on a substrate, for example.

In EUV lithography, EUV lithography masks or reticles that are used to pattern material layers of semiconductor devices need to be inspected occasionally.

What are needed in the art are improved inspection systems and methods for lithography reticles.

### SUMMARY OF THE INVENTION

These and other problems are generally solved or circumvented, and technical advantages are generally achieved, by preferred embodiments of the present invention, which provide inspection systems and methods for lithography reticles.

In accordance with a preferred embodiment of the present invention, an inspection system includes a support for a reticle and a microscope including a lens system. The lens system includes at least one lens comprising at least one Fresnel element, wherein the at least one Fresnel element is non-circular.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an optical system that includes a lens comprising a plurality of Fresnel elements in accordance with an embodiment of the present invention, wherein the Fresnel elements are non-circular;

FIG. 2 shows a front view of a lens comprising a plurality of Fresnel elements comprising an oval shape that are asymmetric about two axes in accordance with an embodiment of the present invention;

FIG. 3 shows a perspective view of the lens shown in FIG. 3;

FIG. 4 shows a front view of a lens comprising a plurality of Fresnel elements asymmetric about two axes in accordance with another embodiment of the present invention, wherein the Fresnel elements comprise a rectangular shape;

FIG. 5 shows an inspection system for a lithography reticle that includes an objective lens comprising plurality of Fresnel elements asymmetric about two axes in accordance with a preferred embodiment of the present invention;

FIG. 6 shows a more detailed view of an area proximate a top surface of the reticle and an objective lens of a lens system of the inspection system shown in FIG. 5;

FIG. 7 shows an inspection system for a lithography reticle that includes a condenser lens comprising plurality of Fresnel elements asymmetric about two axes in accordance with another preferred embodiment of the present invention; and

FIG. 8 shows a perspective view of a lens of an inspection system in accordance with an embodiment of the present invention, wherein the Fresnel elements comprise a plurality of linear gratings.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that embodiments of the present invention provide many applicable inventive concepts that can be embodied in a wide variety of specific contexts. The specific embodiments discussed are merely illustrative of specific ways to make and use the invention, and do not limit the scope of the invention.

EUV lithography reticle microscopes are typically used to inspect EUV lithography reticles. When inspecting a lithography mask or reticle, an EUV lithography reticle microscope projects an image of the source of illumination of the EUV lithography reticle microscope using a lens system. The lenses used in an optical path of conventional EUV lithography reticle microscopes have a circular shape. Large lenses are required to project an image of the source onto an EUV lithography reticle under inspection. However, the size of the lenses, particularly the size of the objective lens of a lens system, is limited, due to the large cost of manufacturing large lenses, for example.

Thus, the lenses in the lens system of an EUV lithography reticle microscope may be inadequate to project or resolve the source of illumination entirely onto an EUV lithography reticle during an inspection process, for example. The point of image focus may be too distant from the objective lens, and the movement of the stage supporting the EUV lithography reticle under inspection may be insufficient to capture the entire image of the source and inspect the entire EUV lithography reticle in a single pass or scan. Thus, regions of the EUV lithography reticle may need to be separately inspected using conventional EUV lithography reticle microscopes, which increases the amount of time required to inspect an EUV lithography reticle and decreases throughput.

Thus, what are needed in the art are improved EUV lithography reticle microscopes for inspecting EUV lithography reticles and improved methods of inspection thereof.

In the past, Fresnel lenses, named after the inventor thereof, Augustin-Jean Fresnel, were often used as lenses in lighthouses. Fresnel lenses focus light towards the center of the path of light, making light emitting from a light source visible over longer distances. Fresnel lenses are used in other applications, such as in lighting instruments for theatre and motion pictures and as magnification lenses on windows of large automobiles or recreational vehicles (RVs), as examples.

Embodiments of the present invention achieve technical advantages by using a Fresnel lens comprising a plurality of non-circular Fresnel elements or zones in the optical path of light of an EUV lithography reticle microscope. A Fresnel lens is used to image a source of the EUV lithography reticle microscope on an EUV lithography reticle under inspection, for example. Implementing the Fresnel lens having non-circular Fresnel elements in the EUV lithography reticle microscope advantageously increases the inspection area of the EUV lithography reticle microscope.

The present invention will be described with respect to preferred embodiments in a specific context, namely implemented in inspection systems for EUV lithography reticles used in EUV lithography systems. Embodiments of the present invention have useful application in inspection systems for EUV lithography reticles and also in other types of production or test lithography reticles, for example. Embodiments of the present invention may also be used in other optical systems, such as microscopes, cameras, telescopes, or binoculars, as examples, to be described further herein.

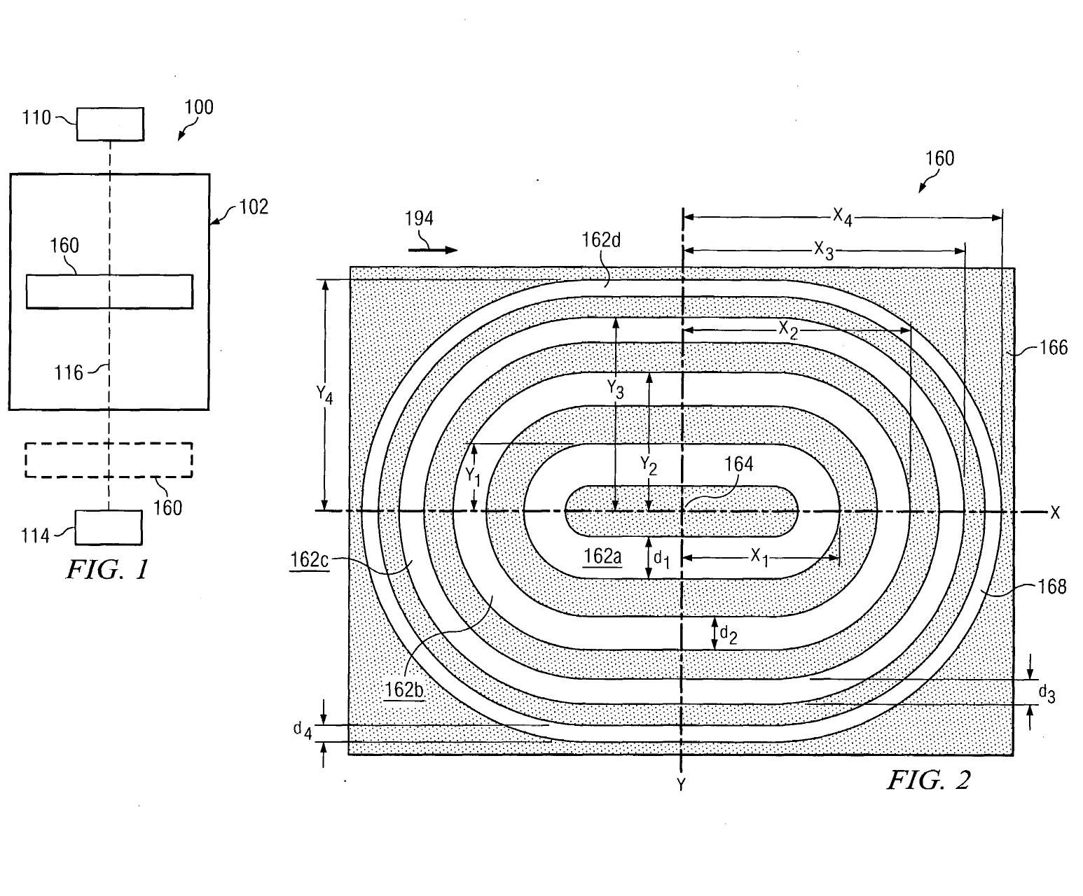

Referring first to FIG. 1, an optical system 100 includes a lens system 102 comprising one or more lenses. The optical system 100 preferably comprises an EUV lithography reticle microscope in some embodiments, and alternatively may comprise other optical systems, such as other types of microscopes or telescopes, for example.

The lens system 102 of the optical system 100 preferably comprises a lens system used in an optical instrument for enlarging images, e.g., of objects or features. The lens system 102 may comprise a lens system used in a light microscope, a telescope, or other types of image magnification devices, for example. The lens system 102 may comprise a lens system used in microscopes for a variety of applications, such as in semiconductor lithography, laboratory science, biology, and medical and biomedical science or research, as examples, although the lens system 102 may also comprise lens systems used in microscopes for other applications. The lens system 102 may comprise a lens system for a microscope that utilizes brightfield, darkfield, or Rheinberg illumination, as examples.

The lens system 102 may also comprise a portion of a telescope used in a variety of applications, such as in space applications, astronomy observation, improved distance viewing for personal use, or other applications. The lens system 102 may comprise a refractor or reflector of a telescope, for example. The lens system 102 may also comprise a lens system for use in magnification viewers for various uses, such as in portable telescopes or binoculars or on scopes mounted on rifles or other weapons, as examples.

The optical system 100 includes a viewer 110 disposed on one side of the lens system 102 and an object 114 to be viewed on the other side of the lens system 102. The viewer 110 may comprise a camera, a digital camera, a charge-coupled device (CCD), a computer, a processor, or a location in the optical system 100 wherein an operator (e.g., a person) may view the object 114 through the lens system 100, as examples, although the viewer 110 may comprise other devices.

The object 114 to be viewed may include a source of illumination (not shown), such as a light or EUV light illumination source, although other sources may also be used. The object 114 may comprise a star or object in the sky, e.g., wherein the lens system 102 comprises a refractor of a telescope, for example. The object 114 may comprise an object to be viewed, e.g., a target a distance away from the lens system 102, and the object 114 may not include a source of illumination, e.g., when the optical system 100 comprises a telescope, binoculars, or a scope, for example.

Preferably, in accordance with embodiments of the present invention, the optical system 100 includes a lens 160 disposed in the optical path 116 that includes at least one Fresnel element that is non-circular. The at least one Fresnel element of the lens 160 may be asymmetric about a first axis with respect to a second axis or may comprise a plurality of linear or lengthwise-extending gratings, to be described further herein. Preferably, in some embodiments of the present invention, the lens 160 is disposed within the lens system 102 along the optical path 116, as shown in FIG. 1. The lens system 102 may include the lens 160 comprising the at least one non-circular Fresnel element, for example. In other embodiments, the lens 160 comprising the at least one non-circular Fresnel element may be separate from the lens system 102, as shown in phantom in FIG. 1.

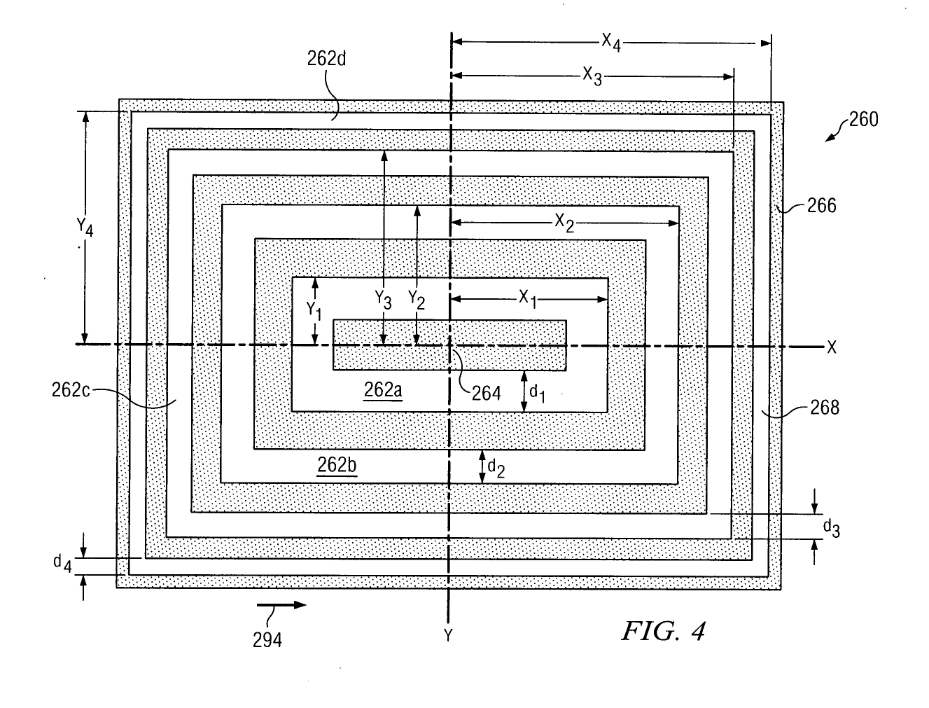

Embodiments of the present invention include microscopes, telescopes, binoculars, cameras, and other optical systems 100 that include at least one Fresnel element 160 that is non-circular. For example, the optical system 100 may include a lens 160 shown in FIG. 2 that is oval or elliptical, in some embodiments. The optical system 100 may include a lens 260 shown in FIG. 4 that is rectangular, in other embodiments. The optical system 100 may alternatively include a lens 560 shown in FIG. 8 that comprises a plurality of linear gratings disposed on and extending lengthwise along one axis, for example.

In a preferred embodiment, for example, an optical system 100 includes a lens 260 such as the lens 260 shown in FIG. 4 disposed in an optical path 116 of the optical system 100. The lens 260 comprises at least one Fresnel element 262a, 262b, 262c, and 262d, the at least one Fresnel element 262a, 262b, 262c, and 262d of the lens 260 having a rectangular shape. The optical system 100 may comprise a microscope, a telescope, a camera, or binoculars, or other optical systems or devices, as examples. The lens 260 comprises a plurality of concentric rectangular-shaped Fresnel elements 262a, 262b, 262c, and 262d, each successively larger Fresnel element 262a, 262b, 262c, and 262d comprising a second width, e.g., width d₂ of Fresnel element 262b that is less than a first width of a smaller adjacent Fresnel element, e.g., width d₁ of Fresnel element 262a that is smaller than Fresnel element 262b.

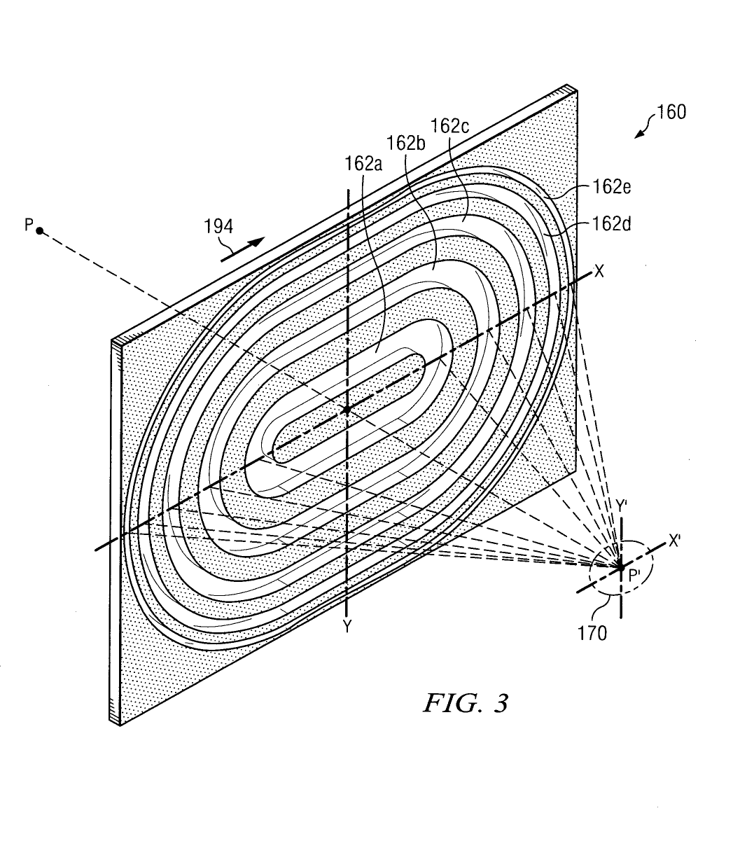

FIG. 2 shows a front view of a lens 160 comprising a plurality of Fresnel elements 162a, 162b, 162c, and 162d comprising an oval or elliptical shape that are asymmetric about two axes x and y of the lens 160 in accordance with a preferred embodiment of the present invention. FIG. 3 shows a perspective view of the lens 160 shown in FIG. 3. Five Fresnel elements 162a, 162b, 162c, 162d, and 162e are shown in FIG. 3, and four Fresnel elements 162a, 162b, 162c, and 162d are shown in FIG. 2; alternatively, a lens 160 may comprise a smaller or greater number of Fresnel elements in accordance with embodiments of the present invention, depending on the optical system the lens 160 is used in, for example.

The Fresnel elements 162a, 162b, 162c, 162d, and 162e in accordance with a preferred embodiment of the present invention comprise a plurality of concentric ellipses or ring-shaped apertures formed in an opaque or optically light-absorbing material 166. The Fresnel elements 162a, 162b, 162c, 162d, and 162e comprise Fresnel zones that are adapted to create constructive and destructive interference of light. The opaque or light-absorbing material 166 patterned with the oval rings may be attached or bonded to a transparent or a light-reflecting material 168, as shown. The Fresnel elements 162a, 162b, 162c, 162d, and 162e preferably comprise a Fresnel lens comprising transparent or light-reflecting oval or elliptical rings formed in an otherwise substantially opaque or light-absorbing reticle 160, for example. The opaque or light-absorbing material 166 preferably comprises chromium (Cr), and the transparent or light-reflecting material 168 preferably comprises quartz or glass, as examples, although other materials may also be used for the lens 160, for example.

The lens 160 comprises at least one Fresnel lens having a first axis x and a second axis y. The second axis y is preferably substantially perpendicular to the first axis x, for example. The Fresnel lens 160 includes at least one Fresnel element 162a, 162b, 162c, 162d, and 162e disposed about, e.g., the Fresnel elements 162a, 162b, 162c, 162d, and 162e comprise the first axis x and the second axis y, as shown. The at least one Fresnel element 162a, 162b, 162c, 162d, and 162e is preferably elongated on the second axis y relative to the first axis x, as shown.

For example, referring to FIG. 2, each of the at least one Fresnel elements 162a, 162b, 162c, and 162d preferably comprises a first radius xₙ on the first axis x and a second radius yₙ on the second axis y, wherein n=1, 2, 3, etc . . . , and wherein the second radius yₙ is smaller than the first radius xₙ. For example, Fresnel element 162a comprises a first radius x₁ on the first axis x and a second radius y₁ on the second axis y, wherein the first radius x₁ is larger than the second radius y₁. Likewise, Fresnel elements 162b, 162c, and 162d comprise a first radius x₂, x₃, and x₄, respectively, on the first axis x and a second radius y₂, y₃, and y₄, respectively, on the second axis y, wherein the first radius x₂, x₃, and x₄ of each Fresnel element 162b, 162c, and 162d is larger than the second radius y₂, y₃, and y₄ of each Fresnel element 162b, 162c, and 162d, as shown.

Each of the Fresnel elements 162a, 162b, 162c, and 162d preferably comprise a constant width or thickness d₁, d₂, d₃, and d₄ for each Fresnel element 162a, 162b, 162c, and 162d, respectively, as shown in FIG. 2, wherein the widths d₁, d₂, d₃, d₄ of the Fresnel elements 162a, 162b, 162c, and 162d are successively smaller for each Fresnel element 162a, 162b, 162c, and 162d moving outwardly away from the origin 164 of the first axis x and the second axis y. Although the radius is not constant for each Fresnel element 162a, 162b, 162c, and 162d, the width d₁, d₂, d₃, and d₄ of each Fresnel element 162a, 162b, 162c, and 162d, respectively, is preferably constant, for example.

For example, in some embodiments, the lens 160 preferably comprises a first Fresnel element 162a having a first minimum radius y₁, a first maximum radius x₁, and a first thickness d₁. The lens 160 preferably comprises a second Fresnel element 162b having a second minimum radius y₂, a second maximum radius x₂, and a second thickness d₂. The second thickness d₂ of the second Fresnel element 162b is preferably less than the first thickness d₁ of the first Fresnel element 162a. The thicknesses d₁, d₂, d₃, and d₄ of the Fresnel elements 162a, 162b, 162c, and 162d preferably are smaller the farther away the Fresnel elements 162a, 162b, 162c, and 162d are from the origin 164, for example.

Furthermore, the second minimum radius y₂ of the second Fresnel element 162b is preferably greater than the first minimum radius y₁ of the first Fresnel element 162a, and the second maximum radius x₂ of the second Fresnel element 162b is preferably greater than the first maximum radius x₁ of the first Fresnel element 162a. Thus, the second Fresnel element 162b and the first Fresnel element 162a are concentric about the origin 164 of the axes x and y.

Likewise, the other Fresnel elements 162c and 162d are preferably also concentric about the origin 164 of the axes x and y with the first Fresnel element 162a and the second Fresnel element 162b. For example, the lens 160 may include at least one third Fresnel element 162c and 162d or a plurality of third Fresnel elements. Each third Fresnel element 162c and 162d preferably has a third minimum radius y₃ or y₄, a third maximum radius x₃ or x₄, and a third thickness d₃ or d₄. The third thickness d₃ or d₄ of the third Fresnel element 162c or 162d is preferably less than the second thickness d₂ of the second Fresnel element 162b. The third minimum radius y₃ or y₄ of the third Fresnel element 162c or 162d is preferably greater than the second minimum radius y₂ of the second Fresnel element 162b. The third maximum radius x₃ or x₄ of the third Fresnel element 162c or 162d is preferably greater than the second maximum radius x₂ of the second Fresnel element 162b, for example.

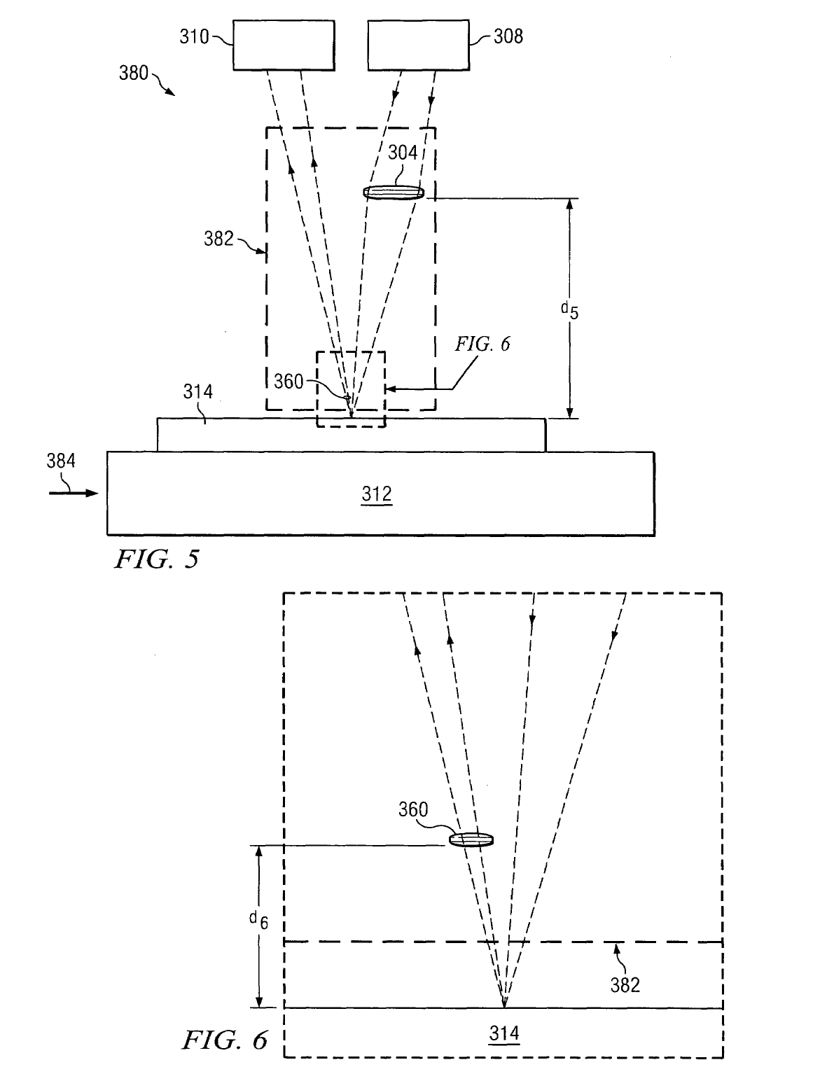

In implementing a Fresnel lens 160 into an optical system 100, either the even or odd diffraction orders of light are blocked by the Fresnel lens 160, for example. The diffraction orders of light in the system may include a zero order (0) and a first order (−1 and +1), for example. By blocking the even or odd diffraction orders of light, only constructive interference of the remaining order results, which results in discrete steps in focal length. These discrete lengths can be tailored with the designed minimum and maximum radii of the concentric Fresnel elements 162a, 162b, 162c, and 162d of the Fresnel lens 160. Thus, a Fresnel lens 160 can be designed that may be used as a lens 360 in a lens system 382 of an EUV lithography reticle microscope 380, as shown in FIG. 5, for example.

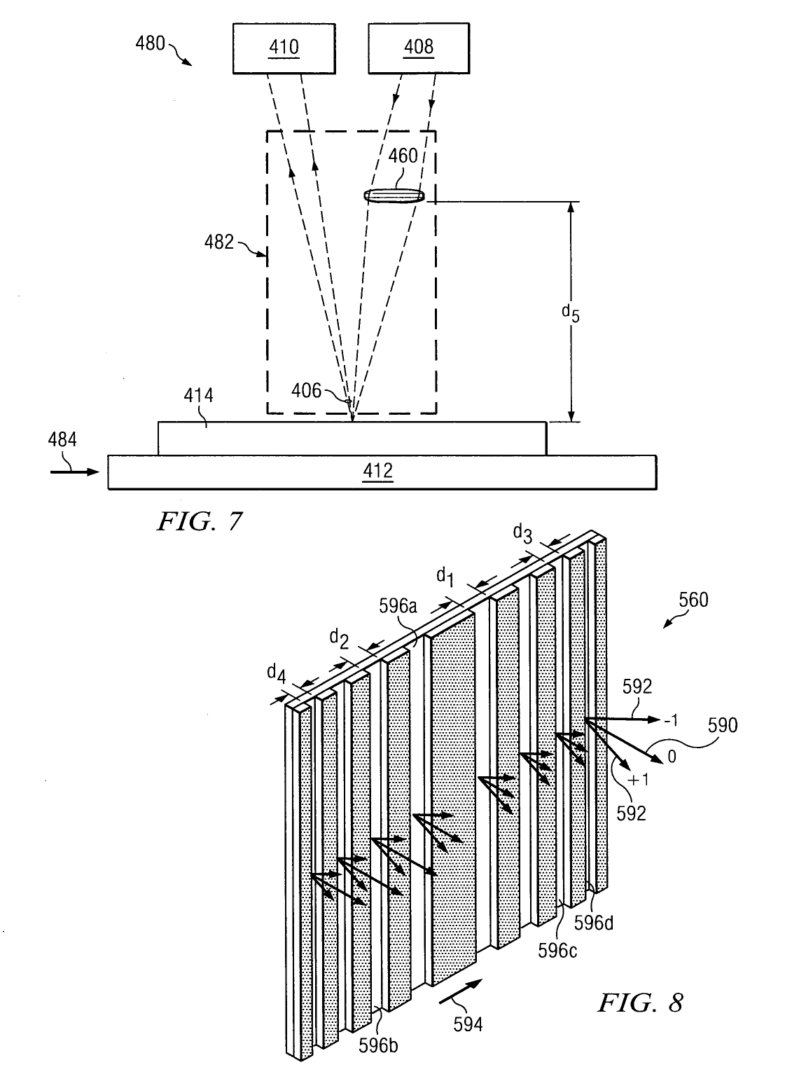

The Fresnel lens 360 (and also lens 160 shown in FIG. 2, lens 260 shown in FIG. 4, lens 460 shown in FIG. 7, and lens 560 shown in FIG. 8) is capable of imaging the source of an illuminator 308 of an EUV lithography reticle microscope 380 onto an EUV reticle 314 within the restricted range of motion of the reticle 314 and the stage or support 312 adapted to support the reticle 314 under test. The support 312 for the reticle 314 is moved while the microscope 380 is used to inspect the reticle 314 in a direction 384, while the lens system 382 remains stationary, for example.

Referring again to FIG. 3, the Fresnel lens 160 in one embodiment comprises an asymmetric oval diffraction grating comprised of alternating opaque or light-absorbing and transparent or light-reflecting Fresnel zones or elements 162a, 162b, 162c, 162d, and 162e. Each transparent or reflective ring of the Fresnel lens 160 has a different width (see widths d₁, d₂, d₃ and d₄ of FIG. 2) than an adjacent transparent or reflective ring, for example. As light impinges upon the Fresnel lens 160 at a wavelength λ, diffracted waves are focused to multiple focal points. Under plane wave illumination, the Fresnel lens 160 diffracts the incident waves and focuses these waves to different locations or different focal points.

In FIG. 3, for example, the first order diffraction waves of the light are focused to the primary or the first-order focal point P′. Advantageously, the focal point P′ may comprise a focal length that is shorter than focal length P, due to the effect of the Fresnel lens 160. The Fresnel lens 160 may be placed in the optical path of an optical system, and may be used to shorten the focal plane P, bringing the focal plane P of the image of the source to the level of the reticle 314 under inspection at focal point P′, as shown in FIG. 5.

FIG. 3 also illustrates that the inspection area 170 may be increased along one axis, e.g., axis x′, as shown in the image plane at focal point P′. Because the lens 160 is asymmetric, the inspection area 170 is increased along the x′ axis compared to the y′ axis. This is an advantage because a larger area of a reticle may be inspected, and the reticle may also be inspected faster. Thus, the throughput of an inspection tool or system such as the EUV lithography microscope 380 shown in FIG. 5 may be increased in accordance with embodiments of the present invention.

FIG. 4 shows a front view of a lens 260 comprising a plurality of Fresnel elements 262a, 262b, 262c, and 262d that are asymmetric about two axes x and y, wherein the Fresnel elements 262a, 262b, 262c, and 262d comprise a rectangular shape. Note that like numerals are used in FIG. 4 as were used in the previous figures, and to avoid repetition, all of the elements are not described in detail again herein. Rather, similar materials and devices x62, x64, x66, x68, etc . . . are preferably used for the various elements shown as were described for the previous figures, where x=1 in FIGS. 1 through 3, and x=2 in FIG. 4.

The lens 260 in this embodiment comprises a plurality of concentric rectangular shaped Fresnel elements 262a, 262b, 262c, and 262d, each successively larger Fresnel element 262b, 262c, 262d comprising a second width (e.g., d₂ of element 262b) that is less than a first width (e.g., d₁ of element 262a) of a smaller adjacent Fresnel element. The novel lens 260 comprising rectangular-shaped Fresnel elements 262a, 262b, 262c, and 262d may be implemented in EUV lithography reticle microscopes such as the ones shown in FIGS. 5 and 7. The novel lens 260 may also be implemented in other types of optical systems, such as the optical system 100 shown in FIG. 1. Embodiments of the present invention also include novel optical systems 100 comprising the novel lens 260, for example.

FIG. 5 shows an inspection system 380 for a lithography reticle 314 that includes an objective lens 360 comprising a plurality of Fresnel elements that are non-circular in accordance with a preferred embodiment of the present invention. The inspection system 380 preferably comprises an EUV reticle microscope that is adapted to inspect an EUV lithography reticle 314. To inspect a reticle, a reticle 314 to be inspected is placed on a support 312 for the reticle 314. The support 312 for the reticle 314 may comprise a stage or other support structure that is adapted to move in the x, y, and z directions, e.g., using one or more motors (not shown). The lens system 382 of the EUV reticle microscope is typically stationary, and the support 312 is moved relative to the lens system 382 while the reticle 314 is inspected, e.g., in a direction 384.

The lens system 382 includes an objective lens 360 proximate the support 312 for the reticle 314 and a condenser lens 304 opposite the objective lens 360 at an opposite end of the lens system 382. The lens system 382 may also comprise a lens support plate, not shown, to which the objective lens 360 and the condenser lens 304 are mounted. In the embodiment shown in FIG. 5, the objective lens 360 preferably comprises a Fresnel lens having at least one non-circular Fresnel element (not shown; see lenses 160, 260, and 560 shown in FIGS. 2, 3, 4, and 8).

The condenser lens 304 is preferably positioned away from the reticle 314 by a greater distance d₅ than the objective lens 360 is spaced apart from the reticle 314, shown in a more detailed view in FIG. 6. For example, the condenser lens 304 may be spaced apart from the reticle 314 by a distance d₅ of about one foot or more, and the objective lens 360 may be spaced apart from the reticle 314 by a distance d₆ of about 10 mm or less, although the distances d₅ and d₆ may alternatively comprise other dimensions. The distance d₆ may comprise a few centimeters, in some embodiments, for example. The objective lens 360 and the condenser lens 304 are preferably spaced apart within the lens system 382 by about one foot or more, for example.

Referring again to FIG. 5, the EUV reticle microscope 380 includes an EUV light source 308 proximate the lens system 382. The EUV light source 308 is also referred to herein as an energy source, for example. The energy source 308 is preferably adapted to generate photons having a wavelength of about 13.5 nm, in some embodiments, for example, although other wavelengths of energy may also be used.

The lens system 382 comprised of the condenser lens 304 and the objective lens 360 is disposed between the EUV light source 308 and the support 312 for the EUV lithography reticle 314. The EUV reticle microscope 380 also includes an energy collector 310 proximate the lens system 382, e.g., which may be proximate the EUV light source 308. The EUV light source 308 is adapted to illuminate the reticle 314 disposed on the support 312 with EUV light, and the energy collector 310 may comprise a camera, charge coupled device (CCD), or other device adapted to capture the EUV light or energy from the EUV light source 308 that is reflected off of the EUV lithography reticle 314.

To inspect a reticle 314, an EUV lithography reticle 314 may be loaded onto the support 312 for the reticle 314, e.g., through a load lock of a chamber by a handler (not shown) in accordance with an embodiment of the present invention. The lens system 382 and the stage 312 of the EUV lithography reticle microscope 380 may be contained within a chamber (not shown), for example, that is pressurized and/or contains a vacuum, for example. The handler picks up the reticle 314 and places the reticle 314 on the support 312 through the load lock.

The reticle 314 preferably comprises an EUV lithography reticle in some embodiments, and preferably comprises one or more reflective materials in some embodiments, such as a Bragg reflection mirror, for example. Alternatively, the reticle 314 may comprise transmissive materials, alternating phase shifting materials, attenuating materials, or combinations thereof with one or more reflective materials, for example. The reticle 314 may comprise a lithography mask comprising opaque or light-absorbing regions and transparent or light-reflecting regions, for example. Embodiments of the present invention may also be implemented in inspection methods and systems for alternating phase-shift masks, in combinations thereof with masks comprising opaque or light-absorbing regions and transparent or light-reflecting regions, and other types of lithography masks, for example.

The reticle 314 may comprise a substantially transparent material comprising quartz glass having a thickness of about ¼″, with an opaque material such as chromium, having a thickness of about 30 nm bonded to the quartz glass. Alternatively, the reticle 314 may comprise about 70 nm of a translucent material such as molybdenum silicon (MoSi), or a bilayer of tantalum and silicon dioxide (Ta/SiO₂). The reticle 314 may also be comprised of multiple layers of silicon and molybdenum that form a reflecting surface and may include an absorber material of tantalum nitride (TaN), for example. Alternatively, the reticle 314 may comprise other transparent or light-reflecting materials and opaque or light-absorbing materials, for example. The reticle 314 may comprise a substantially square substrate, and may comprise a square having sides of about six inches, for example, although alternatively, the reticle 314 may comprise other shapes and sizes.

The EUV lithography reticle microscope 380 illuminates EUV light or other energy from the EUV light source 308, using annular illumination, as an example, although other types of illumination may also be used, through the lens system 382 comprising the condenser lens 306 and the novel objective lens 360, to focus the EUV light on the reticle 314. During the inspection process, the EUV light is reflected off of the reticle 314 through the lens system 382 towards the energy collector 310 or camera that absorbs the EUV light. The camera 310 collects the EUV light and stores the information gathered in the inspection process.

The reticle 314 may be moved in a direction 384 by the stage 312 during an inspection process, as shown. Preferably, the reticle 314 is positioned on the stage 312 so that the axis x having the elongated radius or portion of the Fresnel elements of the Fresnel lens 360 is parallel to the direction of the movement 384. For example, in FIGS. 2 and 3, the reticle 314 shown in FIG. 5 is preferably moved in a direction 384 so that the reticle 314 under test is scanned in a scan direction 194 parallel with the elongated axis x with respect to the Fresnel lens 160 shown in FIGS. 2 and 3. Likewise, in FIG. 4, the reticle 314 shown in FIG. 5 is preferably moved in a direction 384 so that the reticle 314 under test is scanned in a scan direction 294 parallel with the elongated axis x with respect to the Fresnel lens 260 shown in FIG. 4.

The camera 310 captures the image of the source of the light source 308 reflected from the reticle 314, for example. The inspection system 380 may include a computer, software, an operator interface, and other hardware and systems (not shown) adapted to process and store the information collected by the energy collector or camera 310, for example, not shown.

FIG. 7 shows an inspection system 480 for a lithography reticle 414 that includes a condenser lens 460 comprising plurality of Fresnel elements that are non-circular in accordance with another preferred embodiment of the present invention. Again, like numerals are used for the various elements that were described in the previous figures, and to avoid repetition, each reference number shown in FIG. 7 is not described again in detail herein. In this embodiment, the condenser lens 460 of the lens system 482 preferably comprises a Fresnel lens having at least one non-circular Fresnel element, and the objective lens 406 does not comprise a Fresnel lens, for example.

Alternatively, both the condenser lens 460 and the objective lens 406 may comprise an asymmetric or non-circular Fresnel lens having a plurality of asymmetric and/or non-circular Fresnel elements, not shown, in accordance with yet another embodiment of the present invention.

FIG. 8 shows a perspective view of a lens 560 of an inspection system such as inspection systems 380 or 480 shown in FIGS. 5 and 7, respectively, in accordance with an embodiment of the present invention, wherein the Fresnel elements 596a, 596b, 596c, and 596d comprise a plurality of linear gratings. The linear gratings extend lengthwise along one axis (e.g., the y axis) and are successively smaller about either side of a central axis (y, not shown in FIG. 8) of the lens 560; e.g., Fresnel elements 596a have a width d₁ that is larger than the width d₂ of Fresnel elements 596b. Fresnel elements 596c have a width d₃ that is smaller than the width d₂ of Fresnel elements 596b, and Fresnel elements 596d have a width d₄ that is smaller than the width d₃ of Fresnel element 596c.

In this embodiment, referring again to FIG. 5, preferably, the reticle 314 is positioned on the stage 312 so that the gratings comprising the Fresnel elements of the Fresnel lens 360 are positioned perpendicular to the direction of the movement 384 of the reticle 314. For example, in FIG. 8, the reticle 314 shown in FIG. 5 is preferably moved in a direction 384 so that the reticle 314 under test is scanned in a scan direction 594 perpendicular to the lengthwise oriented linear gratings 596a, 596b, 596c, and 596d of the Fresnel lens 560 shown in FIG. 8. Advantageously, the lens 560 in this embodiment is constrained only along one axis and may be made large enough to cover the full width of the reticle 314, for example.

Note that the diffraction orders of light passing through the lens 560 are illustrated in FIG. 8. The 0 order is shown at 590, and the +/−first orders (+1 and −1) are shown at 592.

Embodiments of the present invention also include methods of manufacturing semiconductor devices (not shown). For example, in accordance with a preferred embodiment of the present invention, a method of manufacturing a semiconductor device includes providing an inspection system 380 or 480 (see FIGS. 5 and 7) for a lithography reticle 314 or 414, the inspection system 380 or 480 comprising a support 312 or 412 for the lithography reticle 314 or 414. The inspection system 380 or 480 comprises a microscope comprising an energy source 308 or 408, a lens system 382 or 482 disposed between the support 312 or 412 for the lithography reticle 314 or 414 and the energy source 308 or 408, and an energy collector 310 or 410 proximate the lens system 382 or 482. The lens system 382 or 482 includes a lens 160, 260, 360, 460, or 560 (see FIGS. 1 through 8) comprising at least one Fresnel element, the at least one Fresnel element being non-circular.

The method of manufacturing the semiconductor device includes disposing a lithography reticle 314 or 414 on the support 312 or 412 for the lithography reticle of the inspection system, inspecting the lithography reticle 314 or 414 using the inspection system 380 or 480, and affecting a semiconductor device using the lithography reticle 314 or 414. The method may further comprise, after inspecting the lithography reticle 314 or 414 using the novel inspection systems 380 or 480 described herein: cleaning the lithography reticle 314 or 414; replacing the lithography reticle 314 or 414; altering the lithography reticle 314 or 414; or altering a parameter of a lithography system (not shown) used to affect the semiconductor device using the lithography reticle 314 or 414, for example.

Affecting the semiconductor device using the lithography reticle 314 or 414 inspected using the novel inspection systems 380 or 480 and inspection methods described herein may comprise providing a workpiece, the workpiece including a material layer disposed thereon and a layer of photosensitive material disposed over the material layer, and patterning the layer of photosensitive material using the lithography reticle 314 or 414, for example. Affecting the semiconductor device using the lithography reticle 314 or 414 may comprise using the layer of photosensitive material as a mask to alter the material layer of the workpiece, and removing the layer of photosensitive material.

Altering the material layer of the workpiece may comprise removing at least a portion of the material layer, depositing a second material layer over the material layer, or implanting a substance into the material layer, as examples, although alternatively, the material layer of the workpiece may be altered in other ways. The material layer of the semiconductor device may comprise a conductive material, an insulating material, a semiconductive material, or multiple layers or combinations thereof, as examples.

Embodiments of the present invention also include novel inspection methods using the inspection systems 100, 240, or 360 described herein. For example, in accordance with one embodiment, an inspection method preferably comprises providing an inspection system 380 or 480 for a lithography reticle 314 or 414, the inspection system 380 or 480 comprising a support 312 or 412 for a lithography reticle 314 or 414 and the other elements shown in FIGS. 5, 6, and 7 that were previously described herein. The inspection system 380 or 480 preferably comprises a lens system 382 or 482 including a lens 160, 260, 360, 460, or 560 comprising at least one Fresnel element, the at least one Fresnel element being non-circular.

The inspection method includes disposing a lithography reticle 314 or 414 on the support 312 or 412 for the lithography reticle of the inspection system 380 or 480, and inspecting the lithography reticle 314 or 414. The lens 160 or 260 may comprise a first axis (the y axis, in this embodiment) and a second axis (x), wherein at least one Fresnel element is elongated on the second axis (x) relative to the first axis (y) of the lens 160 or 260. Inspecting the lithography reticle 314 or 414 may comprise moving the lens 160 or 260 in a direction 194 or 294 parallel to the second axis (x) while inspecting the lithography reticle 314 and 414, for example.

In other embodiments, the lens 560 (see FIG. 8) comprises a first axis (vertical) and a second axis orthogonal to the first axis, wherein the at least one Fresnel element 596a, 596b, 596c, and 596d comprises a plurality of linear gratings that extend in lengthwise across the lens 560 in a direction parallel to the first axis (the y axis, in this embodiment) of the lens 560. Inspecting the lithography reticle 314 or 414 in this embodiment preferably comprises moving the lens 560 in a direction parallel 594 to the second axis (x) while inspecting the lithography reticle 314 or 414, for example.

Embodiments of the present invention also include semiconductor devices patterned using the lithography reticles 314 or 414 inspected using the novel inspection systems 380 and 480 and methods described herein, for example. Features of semiconductor devices patterned using the lithography reticles 314 or 414 inspected using the inspection systems 380 and 480 and methods described herein may comprise transistor gates, conductive lines, vias, capacitor plates, and other features, as examples. Embodiments of the present invention may be used to pattern features of memory devices, logic circuitry, and/or power circuitry, as examples, although other types of ICs may also be fabricated using the novel lithography reticles 314 or 414 inspected using the novel inspection systems 380 and 480 and methods described herein.

Embodiments of the present invention are particularly advantageous when used to inspect reticles 314 and 414 used in lithography systems that utilize extreme ultraviolet (EUV) light, e.g., at a wavelength of about 13.5 nm, for example. Embodiments of the present invention are also advantageous when used to inspect reticles 314 and 414 used in deep ultraviolet (DUV) lithography systems, immersion lithography systems, or other lithography systems that use visible light for illumination, as example. Embodiments of the present invention may be implemented to inspect reticles 314 and 414 used in lithography systems, steppers, scanners, step-and-scan exposure tools, or other exposure tools, as examples. The embodiments described herein are implementable to inspect reticles 314 and 414 used in lithography systems that use both refractive and reflective optics and for lenses with high and low numerical apertures (NAs), for example.

Advantages of embodiments of the present invention include providing novel inspection systems 380 and 480 and methods for testing and inspecting lithography reticles 314 and 414. The novel inspection systems 380 and 480 may be used to determine if lithography reticles 314 or 414 need to be cleaned or replaced, or to ascertain the effectiveness of cleaning processes used to clean the lithography reticles 314 and 414, for example.

Advantages of other embodiments of the present invention include providing novel lenses 260 (see FIG. 4) comprising Fresnel elements 262a, 262b, 262c, and 262d that are rectangular in shape, and optical systems 100 (see FIG. 1) that include the novel rectangular-shaped Fresnel element-containing lenses 260, for example.

In the embodiments shown in FIGS. 2, 3, and 4, the lenses 160 and 260 comprise non-circular Fresnel elements that are expanded or lengthened along one axis (the x axis) compared to the other axis (the y axis). The lengthening of the Fresnel elements along one of the axes may be achieved and installed in an inspection system 380 or 480 such that the lenses 160 and 260 advantageously do not block the light path of illumination of a reticle 314 or 414 under inspection, for example.

The novel asymmetric lenses 160, 260, 360, 460, and 560 with non-circular Fresnel elements provide the ability to inspect EUV lithography reticles 314 and 414 more quickly without loss of resolution. Increased throughput of inspection systems 380 and 480 for lithography reticles 314 and 414 is achieved by the novel embodiments of the present invention.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An inspection system, comprising:
a support for a reticle; and
a microscope including a lens system, the lens system including at least one lens comprising at least one Fresnel element, wherein the at least one Fresnel element of the at least one lens of the lens system is non-circular.

2. The inspection system according to claim 1, wherein the at least one Fresnel element comprises a first axis and a second axis, wherein the at least one Fresnel element is elongated on the second axis.

3. The inspection system according to claim 2, wherein the at least one Fresnel element comprises a first radius on the first axis and a second radius on the second axis, wherein the second radius is larger than the first radius.

4. The inspection system according to claim 2, further comprising a means for moving the support for the reticle relative to the at least one lens in a direction parallel to the second axis while the inspection system is used for inspection of a reticle disposed on the support for the reticle.

5. The inspection system according to claim 1, wherein the lens system comprises a Fresnel lens including the at least one Fresnel element, wherein the Fresnel lens comprises an objective lens or a condenser lens of the lens system of the microscope.

6. The inspection system according to claim 1, wherein the at least one Fresnel element comprises an oval shape or a rectangular shape, or wherein the at least one Fresnel element comprises a plurality of linear gratings.

7. An inspection system, comprising:
a support for an extreme ultraviolet (EUV) lithography reticle; and
an EUV reticle microscope, the EUV reticle microscope including an EUV light source, a lens system disposed between the EUV light source and the support for the EUV lithography reticle, and an energy collector proximate the lens system, the lens system of the EUV reticle microscope including a lens comprising at least one Fresnel element, wherein the at least one Fresnel element of the lens is non-circular.

8. The inspection system according to claim 7, wherein the lens comprises at least one Fresnel lens having a first axis and a second axis, the at least one Fresnel element being disposed on the first axis and the second axis, and wherein the at least one Fresnel element is elongated along the second axis relative to the first axis.

9. The inspection system according to claim 7, wherein the lens comprises a first Fresnel element having a first minimum radius, a first maximum radius, and a first thickness; wherein the lens comprises a second Fresnel element having a second minimum radius, a second maximum radius, and a second thickness; wherein the second thickness is less than the first thickness; wherein the second minimum radius is greater than the first minimum radius; and wherein the second maximum radius is greater than the first maximum radius.

10. The inspection system according to claim 9, wherein the lens comprises at least one third Fresnel element having a third minimum radius, a third maximum radius, and a third thickness; wherein the third thickness is less than the second thickness; wherein the third minimum radius is greater than the second minimum radius; and wherein the third maximum radius is greater than the second maximum radius.

11. The inspection system according to claim 7, wherein the lens comprises a transparent or reflective material and an opaque or absorbent material disposed over the transparent or reflective material, wherein the at least one Fresnel element comprises a pattern in the opaque or absorbent material of the lens.

12. A lens, comprising:
at least one Fresnel element, the at least one Fresnel element of the lens having a rectangular shape.

13. The lens according to claim 12, wherein the lens comprises an opaque or light-absorbing material and a transparent or light-reflecting material disposed over the opaque or light-absorbing material, and wherein the at least one Fresnel element comprises a pattern in the opaque or light-absorbing material.

14. An optical system including the lens according to claim 12 disposed in an optical path of the optical system.

15. The optical system according to claim 14, wherein the optical system comprises a microscope, a telescope, a camera, or binoculars.

16. The optical system according to claim 14, wherein the lens comprises a plurality of concentric rectangular-shaped Fresnel elements, each successively larger Fresnel element comprising a second width that is less than a first width of a smaller adjacent Fresnel element.

17. A method of manufacturing a semiconductor device, the method comprising:
providing an inspection system for a lithography reticle, the inspection system comprising a support for the lithography reticle, the inspection system comprising a microscope including an energy source, a lens system disposed between the support for the lithography reticle and the energy source, and an energy collector proximate the lens system, the lens system including a lens comprising at least one Fresnel element, the at least one Fresnel element being non-circular;
disposing a lithography reticle on the support for the lithography reticle of the inspection system;
inspecting the lithography reticle using the inspection system; and
affecting a semiconductor device using the lithography reticle.

18. The method according to claim 17, further comprising, after inspecting the lithography reticle using the inspection system: cleaning the lithography reticle; replacing the lithography reticle; altering the lithography reticle; or altering a parameter of a lithography system used to affect the semiconductor device using the lithography reticle.

19. The method according to claim 17, wherein affecting the semiconductor device using the lithography reticle comprises:
providing a workpiece, the workpiece including a material layer disposed thereon and a layer of photosensitive material disposed over the material layer; and
patterning the layer of photosensitive material using the lithography reticle.

20. The method according to claim 17, wherein affecting the semiconductor device using the lithography reticle comprises using the layer of photosensitive material as a mask to alter the material layer of the workpiece, and removing the layer of photosensitive material.

21. The method according to claim 20, wherein altering the material layer of the workpiece comprises removing at least a portion of the material layer, depositing a second material layer over the material layer, or implanting a substance into the material layer.

22. The method according to claim 20, wherein providing the workpiece comprises providing a workpiece comprising a material layer that comprises a conductive material, an insulating material, a semiconductive material, or multiple layers or combinations thereof.

23. A semiconductor device manufactured in accordance with the method of claim 20.

24. An inspection method, comprising:
providing an inspection system for a lithography reticle, the inspection system comprising a support for a lithography reticle, the inspection system comprising a microscope comprising an energy source, a lens system disposed between the support for the lithography reticle and the energy source, and an energy collector proximate the lens system, the lens system including a lens comprising at least one Fresnel element, the at least one Fresnel element being non-circular;
disposing a lithography reticle on the support for the lithography reticle of the inspection system; and
inspecting the lithography reticle using the microscope.

25. The method according to claim 24, wherein inspecting the lithography reticle using the microscope comprises illuminating the lithography reticle using the energy source, and analyzing energy collected by the energy collector.

26. The method according to claim 24, wherein the lens comprises a first axis and a second axis, wherein the at least one Fresnel element is elongated on the second axis relative to the first axis of the lens, and wherein inspecting the lithography reticle using the microscope comprises moving the lens in a direction parallel to the second axis while inspecting the lithography reticle.

27. The method according to claim 24, wherein the lens comprises a first axis and a second axis, wherein the at least one Fresnel element comprises a plurality of linear gratings that extend in a direction parallel to the first axis of the lens, and wherein inspecting the lithography reticle using the microscope comprises moving the lens in a direction parallel to the second axis while inspecting the lithography reticle.
